(19) United States
(12) Patent Application Publication
(10) Pub. No.: US 2005/0105268 A1
(43) Pub. Date: May 19, 2005

(54) Back cover protector

(75) Inventors: Pei Chen, Taipei City (TW); Pi-Yun Lee, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 10/832,384

(22) Filed: Apr. 27, 2004

(30) Foreign Application Priority Data
Nov. 14, 2003 (TW) 092220229

(51) Int. Cl. H05K 7/20

(52) U.S. Cl. 361/692

(57) ABSTRACT

A back cover protector is mounted on a back side of a server, the back side having a plurality of holes, the back cover protector comprises a back panel cover having at least two binding units, a first locking element, a plurality of heat-dissipating holes and at least one I/O port hole, wherein the back side of the server is covered with the back panel cover by sticking binding units to the plurality of holes on the back side; and a second locking element fixed on the back side of the server corresponding to the first locking element and locking with the first locking element.

### BACKGROUND OF THE INVENTION

1. Field of the Invention

The present invention relates to a back cover protector and, more particularly, to a back cover protector on a back side of a server.

2. Description of the Related Art

In the prior art, an I/O port on the back of the server is not protected by any mechanism, and so its important connecting end, such as a USB or FDD connection port, has no protection. However, any accidents may result in a bad connection, or even a complete connection failure, which may cause the difficulty in network management.

Since there is no protection mechanism, other important parts may be taken from the back of the server, which may jeopardize the security of internal data.

Therefore, it is desirable to provide a back cover protector to mitigate and/or obviate the aforementioned problems.

### SUMMARY OF THE INVENTION

A main objective of the present invention is to provide a back cover protector to protect important connection ports on the back of a server, avoid the damage on the rear surface of a server, and improve network management.

In order to achieve the above mentioned objective, the back cover protector of the present invention is mounted on a back side of a server, the back side having a plurality of holes, the back cover protector includes a back panel cover having at least two binding units, a first locking element, a plurality of heat-dissipating holes and at least one I/O port hole, wherein the back side of the server is covered with the back panel cover by sticking the binding units to the plurality of holes on the back side; and a second locking element fixed on the back side of the server corresponding to the first locking element and locking with the first locking element. Other objects, advantages, and novel features of the invention will become more apparent from the following detailed description when taken in conjunction with the accompanying drawings.

### BRIEF DESCRIPTION OF THE DRAWINGS

FIG. 1 is a perspective drawing of a preferred embodiment according to the present invention.

FIG. 2A and FIG. 2B are schematic drawings of the embodiment depicted in FIG. 1.

FIG. 3 is a schematic drawing of a locking mechanism according to the present invention.

FIG. 4 is a schematic drawing of the preferred embodiment according to the present invention.

FIG. 5 is a schematic drawing of the preferred embodiment according to the present invention.

### DETAILED DESCRIPTION OF THE PREFERRED EMBODIMENT

In the present invention, a back cover protector includes two binding units integrated with an edge of a back panel cover to fix the back panel cover on a back side of a server. The binding units can be a hook, which hooks correspondingly into a plurality of holes on the back side of the server. The plurality of holes on the back side of the server are heat-dissipating heat-dissipating holes. A first locking element is an access sheet turned by a key, and a second locking element is a slot for the key to turn the access sheet therein. In order to lock the back cover protector to the back side of the server, the key is turned to rotate the access sheet into the slot. The second locking element uses at least one screw to fasten to the back side of the server. Furthermore, according to the design of the server, at least one I/O port hole is formed on the back panel cover.

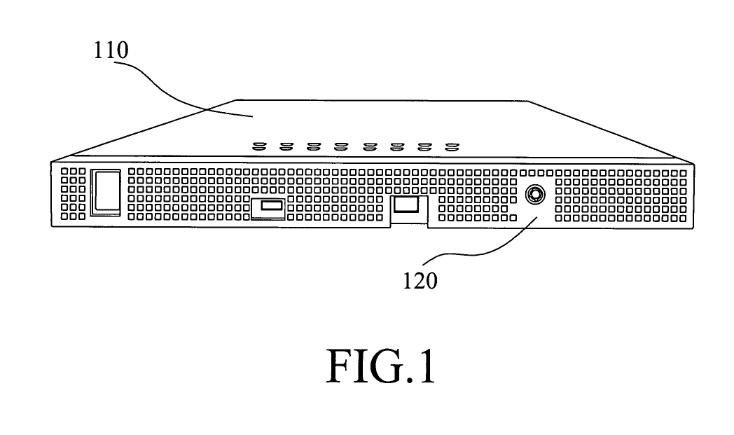

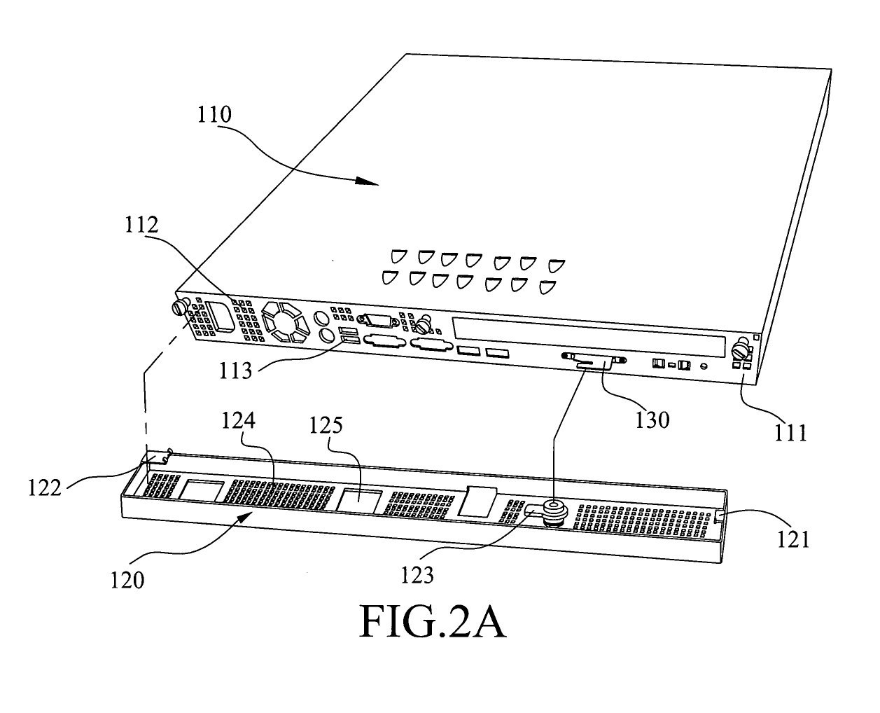

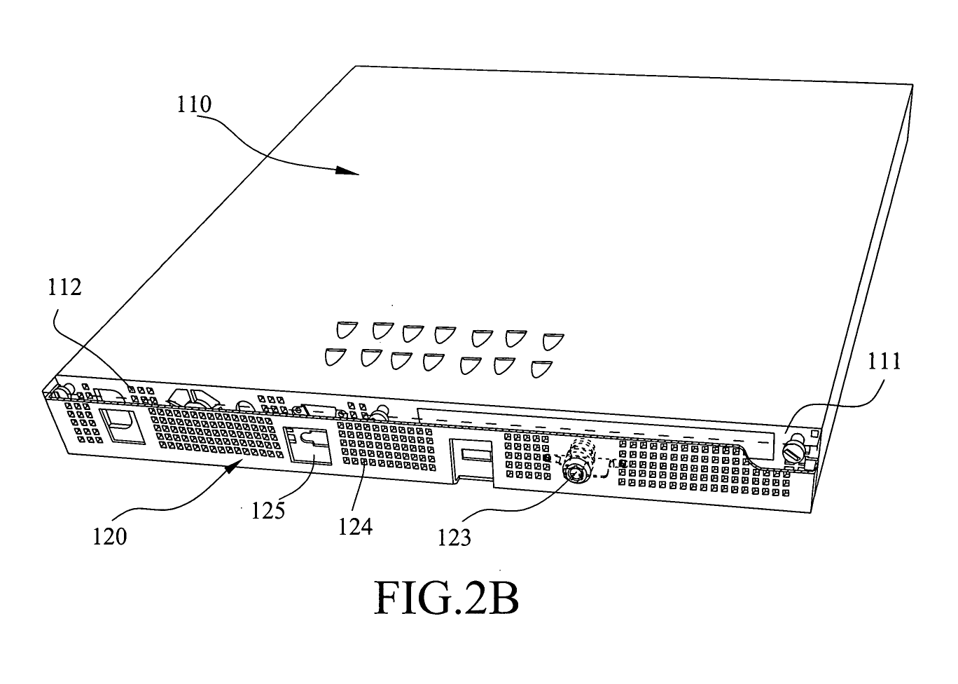

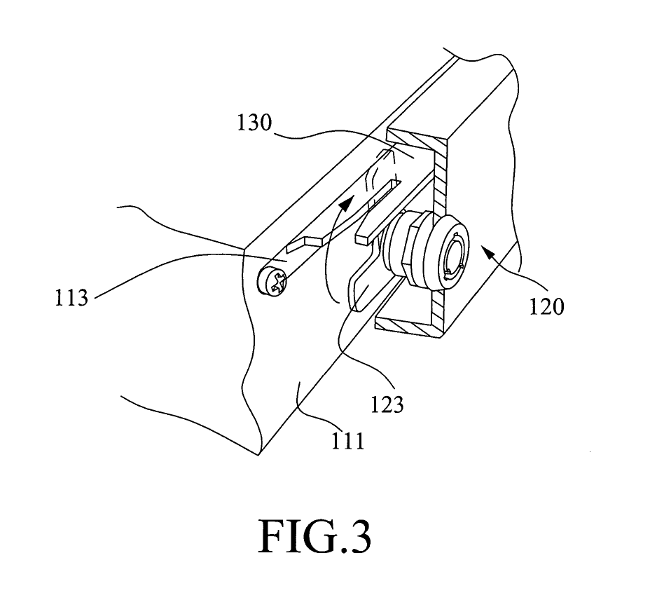

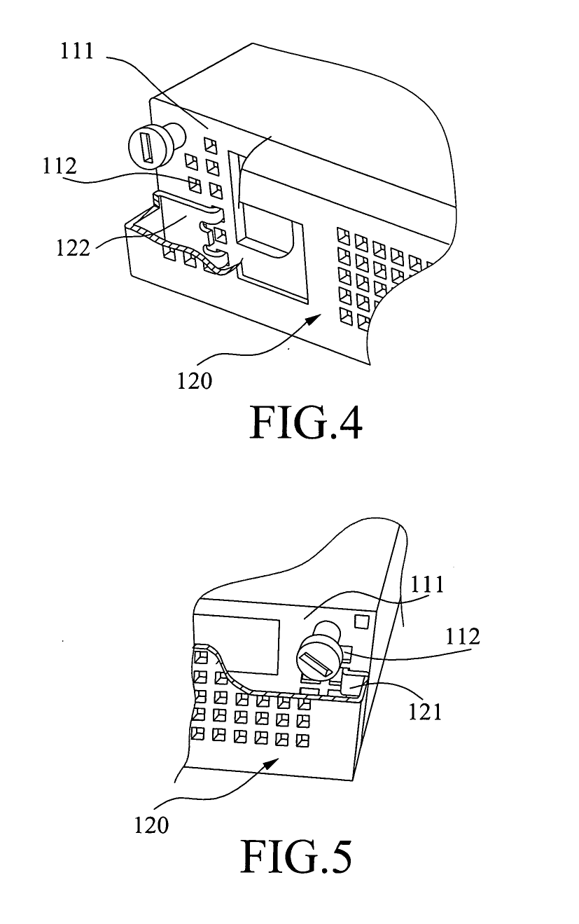

For a preferred embodiment, please refer to FIG. 1, FIG. 2A, FIG. 2B and FIG. 3. The back panel cover is assembled on a back side 111 of a server 110, and the back side 111 has a plurality of heat-dissipating holes 112 and a plurality of I/O ports 113. The back cover protector includes a back panel cover 120 and a second locking element 130. The back panel cover 120 has two binding units (i.e. hooks) 121 and 122, a first locking element 123, a plurality of heat-dissipating holes 124 and a plurality of I/O port holes 125. The back side 111 of the server 110 is covered with the back panel cover 120 by hooking the binding units 121 and 122 onto the heat-dissipating holes 112 on the back side 111 of the server 110. The two binding units 121 and 122 are located on and integrated with an edge of the panel back cover 121. The second locking element 130 is fixed in any hole on the back side of the server by a screw, corresponds to the first locking element 123, and is locked with the first locking element 123. The first locking element is an access sheet turned by a key, and a second locking element 130 is a slot for the key to turn the access sheet therein. In order to lock the back cover protector to the back side of the server, the key is turned to rotate the access sheet into the slot to lock the panel back cover 120. The I/O port holes 125 can be placed according to the positions of the connecting port of the server. After the back cover protector in this embodiment is mounted on a back side of a server, the binding units stuck in the heat-dissipating holes is shown in FIG. 4 and FIG. 5.

The back cover protector of the present invention can protect the back side of the server to prevent the connecting ends of the server from disconnecting or being damaged in accidents. Furthermore, the back cover protector of the present invention can also prevent the important parts of the server from being stolen, and improves the operation efficiency of network management.

Although the present invention has been explained in relation to its preferred embodiment, it is to be understood that many other possible modifications and variations can be made without departing from the spirit and scope of the invention as hereinafter claimed.

1. A back cover protector mounted on a back side of a server, the back side having a plurality of holes, the back cover protector comprising:
a back panel cover having at least two binding units, a first locking element, a plurality of heat-dissipating holes and at least one I/O port hole, wherein the back side of the server is covered with the back panel cover by sticking binding units to the plurality of holes on the back side of the server; and
a second locking element fixed on the back side of the server corresponding to the first locking element and locking with the first locking element.

2. The back cover protector as claimed in claim 1, wherein the two binding units are integrated with an edge of the back panel cover.

3. The back cover protector as claimed in claim 1, wherein thebinding unit is a hook and hooks in the plurality of holes on the back side.

4. The back cover protector as claimed in claim 3, wherein the plurality of holes on the back side of the server are heat-dissipating holes.

5. The back cover protector as claimed in claim 1, wherein the first locking element is an access sheet capable of being turned by a key, and the second locking element is a slot for the key to turn the access sheet therein.

6. The back cover protector as claimed in claim 1, wherein the second locking element is fixed to the back side of the server by least one screw.
